(19) United States
(12) Patent Application Publication
(10) Pub. No.: US 2024/0230777 A9
(43) Pub. Date: Jul. 11, 2024

(54) BATTERY MEASUREMENT DEVICE

(71) Applicant: DENSO CORPORATION, Kariya-city (JP)

(72) Inventors: Masaaki KITAGAWA, Kariya-city (JP); Isao ISHIBE, Kariya-city (JP)

(73) Assignee: DENSO CORPORATION, Kariya-city (JP)

(21) Appl. No.: 18/402,069

(22) Filed: Jan. 2, 2024

Related U.S. Application Data
(63) Continuation of application No. PCT/JP22/22533, filed on Jun. 2, 2022.

(30) Foreign Application Priority Data
Jun. 30, 2021 (JP) 2021-109558

(51) Int. Cl. G01R 31/389; G01R 31/374; G01R 31/3828; H01M 10/48

(52) U.S. Cl. CPC G01R 31/389; G01R 31/374; G01R 31/3828; H01M 10/48

(57) ABSTRACT

A battery measurement device that measures a state of a secondary battery includes: a signal control section that causes an alternating-current signal to be outputted from the secondary battery or inputs an alternating-current signal to the secondary battery; a current measurement section that measures the alternating-current signal; a response signal measurement section that measures a response signal of the secondary battery responsive to the alternating-current signal; and a calculation section that calculates information regarding a complex impedance of the secondary battery based on measurement results of the alternating-current signal measured by the current measurement section and the response signal measured by the response signal measurement section. The arithmetic section calculates the information regarding the complex impedance after waiting for the measurement result of the alternating-current signal to reach a steady state after start of the input/output of the alternating-current signal by the signal control section and outputs a calculation result.

### CROSS-REFERENCE TO RELATED APPLICATION

This application is the U.S. bypass application of International Application No. PCT/JP2022/022533 filed on Jun. 2, 2022 which designated the U.S. and claims priority to Japanese Patent Application No. 2021-109558 filed on Jun. 30, 2021, the contents of both of which are incorporated herein by reference.

### TECHNICAL FIELD

The present disclosure relates to a battery measurement device.

### BACKGROUND

To measure a state of a secondary battery, a complex impedance (an alternating-current impedance) of the secondary battery has typically been measured (for example, WO2020/003841). According to the disclosure of WO2020/003841, alternating current such as a sinusoidal current is caused to flow through a secondary battery from an oscillator, the resulting response signal (voltage variation) and alternating current are measured, and complex impedance characteristics are measured based on the measurement result. Then, a deterioration state or the like of the secondary battery is determined based on the complex impedance characteristics.

### SUMMARY

A battery measurement device that measures a state of a secondary battery includes: a signal control section that causes an alternating-current signal to be outputted from the secondary battery or inputs an alternating-current signal to the secondary battery; a current measurement section that measures the alternating-current signal; a response signal measurement section that measures a response signal of the secondary battery responsive to the alternating-current signal; and a calculation section that calculates information regarding a complex impedance of the secondary battery based on measurement results of the alternating-current signal measured by the current measurement section and the response signal measured by the response signal measurement section, in which the arithmetic section calculates the information regarding the complex impedance after waiting for the measurement result of the alternating-current signal to reach a steady state after start of the input/output of the alternating-current signal by the signal control section and outputs a calculation result.

The arithmetic section is configured to determine that the measurement result reaches the steady state at elapse of a predetermined preparation time after the start of the input/output of the alternating-current signal to the secondary battery by the signal control section and output the calculation result.

The preparation time is set in accordance with a frequency of the alternating-current signal to be inputted/outputted during a period before the measurement result reaches the steady state after the start of the input/output of the alternating-current signal by the signal control section.

### BRIEF DESCRIPTION OF THE DRAWINGS

The above features of the present disclosure will be made clearer by the following detailed description, given referring to the appended drawings. In the accompanying drawings:

FIG. 1 is a schematic configuration diagram of a power source system;

FIG. 2 is a configuration diagram of a battery measurement device;

FIG. 3 is a flowchart of an impedance calculation process;

FIG. 4 is a flowchart of a preparation process;

FIG. 5 is a flowchart of a preparation process of a second embodiment;

FIG. 6 is a diagram illustrating a relationship between complex impedance and frequency;

FIGS. 7A and 7B are diagrams illustrating a relationship between a phase and a current value of an alternating-current signal for preparation at the time of start;

FIG. 8 is a diagram illustrating the alternating-current signal for preparation;

FIG. 9 is a flowchart of a preparation process of a third embodiment; and

FIG. 10 is a flowchart of a preparation process of a fourth embodiment.

### DETAILED DESCRIPTION OF THE PREFERRED EMBODIMENTS

A state of a circuit for measuring an impedance or a secondary battery is not always constant and the state may change depending on application of alternating current. For example, a shunt resistance provided for measuring alternating current may generate heat causing a change in temperature due to the application of alternating current. A change in the temperature of the shunt resistance causes a change in a resistance value of the shunt resistance, thus leading to a change in amplitude of alternating current flowing through a secondary battery. As a result, there is a possibility that an impedance has an error due to the occurrence of an error in the measurement result of the alternating current.

The present disclosure is made in view of the above problem and an object of the present disclosure is to provide a battery measurement device that can reduce error in the impedance.

A battery measurement device, as a means for solving the above problem, that measures a state of a secondary battery includes: a signal control section that causes an alternating-current signal to be outputted from the secondary battery or inputs an alternating-current signal to the secondary battery; a current measurement section that measures the alternating-current signal; a response signal measurement section that measures a response signal of the secondary battery responsive to the alternating-current signal; and a calculation section that calculates information regarding a complex impedance of the secondary battery based on measurement results of the alternating-current signal measured by the current measurement section and the response signal measured by the response signal measurement section, in which the arithmetic section calculates the information regarding the complex impedance after waiting for the measurement result of the alternating-current signal to reach a steady state after start of the input/output of the alternating-current signal by the signal control section and outputs a calculation result.

The arithmetic section is configured to determine that the measurement result reaches the steady state at elapse of a predetermined preparation time after the start of the input/output of the alternating-current signal to the secondary battery by the signal control section and output the calculation result.

The preparation time is set in accordance with a frequency of the alternating-current signal to be inputted/outputted during a period before the measurement result reaches the steady state after the start of the input/output of the alternating-current signal by the signal control section.

This reduces a rise in temperature due to the alternating-current signal reducing a calculation accuracy of the complex impedance during calculation of the information regarding the complex impedance, which makes it possible to improve calculation accuracy of the complex impedance.

### First Embodiment

Description will be given below on a first embodiment where a “battery measurement device” is used in a power source system for a vehicle (for example, a hybrid vehicle or an electric vehicle) with reference to the drawings.

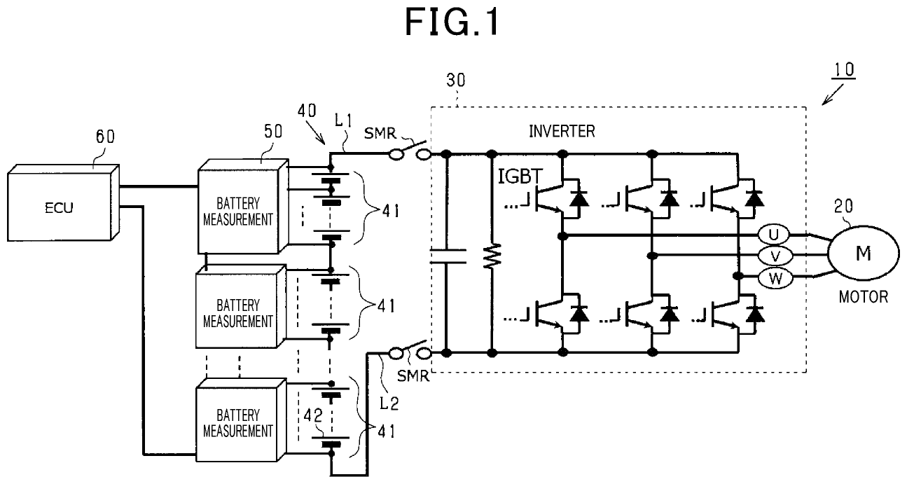

As illustrated in FIG. 1, a power source system 10 includes a motor 20 serving as a rotating electrical machine, an or inverter 30 serving as an electric power converter that applies a three-phase current to the motor 20, a chargeable/dischargeable assembled battery 40, a battery measurement device 50 that measures a state of the assembled battery 40, and an ECU 60 that controls the motor 20 and the like.

The motor 20, which is an in-vehicle main machine, is able to perform power transfer with a non-illustrated drive wheel. In the present embodiment, a three-phase permanent magnet synchronous motor is used as the motor 20.

The inverter 30 includes a full-bridge circuit with upper and lower arms as many as the number of phases of phase windings and currents flowing through the individual phase windings are adjusted by ON/OFF switching of switches (semiconductor switching elements) provided in the respective arms.

The inverter 30 includes a non-illustrated inverter control device and the inverter control device performs energization control by ON/OFF switching of the individual switches of the inverter 30 based on a variety of detection information regarding the motor 20 or a requirement for powered driving and generation of electric power. The inverter control device thus causes an electric power to be supplied from the assembled battery 40 to the motor 20 via the inverter 30 to cause powered driving of the motor 20. In addition, the inverter control device causes the motor 20 to generate an electric power based on a power from the drive wheel and causes the generated electric power to be converted and supplied to the assembled battery 40 via the inverter 30 to charge the assembled battery 40.

The assembled battery 40 is electrically connected to the motor 20 via the inverter 30. The assembled battery 40, which has an interterminal voltage of, for example, one hundred V or more, includes a plurality of battery modules 41 connected in series. The battery modules 41 each include a plurality of battery cells 42 connected in series. For example, lithium ion secondary batteries or nickel-metal hydride secondary batteries are usable as the battery cells 42. The battery cells 42 are each a secondary battery including an electrolyte and a plurality of electrodes.

As illustrated in FIG. 1, a positive-side terminal of an electric load such as the inverter 30 is connected to a positive-side power source path L1 connected to a positive-side power source terminal of the assembled battery 40. Likewise, a negative-side terminal of the electric load such as the inverter 30 is connected to a negative-side power source path L2 connected to a negative-side power source terminal of the assembled battery 40. It should be noted that the positive-side power source path L1 and the negative-side power source path L2 are each provided with a relay switch SMR (system main relay switch) and energization and de-energization are switchable using the relay switch SMR.

The battery measurement device 50 is a device that measures a state of charge (SOC), a state of deterioration (SOH), and the like of each of the battery cells 42. The battery measurement device 50, which is connected to the ECU 60, outputs a state of each of the battery cells 42 or the like. A configuration of the battery measurement device 50 will be described later.

The ECU 60 issues a requirement for powered driving and generation of electric power to the inverter control device based on a variety of information. The variety of information includes, for example, information regarding operations of an accelerator and brake, a vehicle speed, the state of the assembled battery 40, and the like.

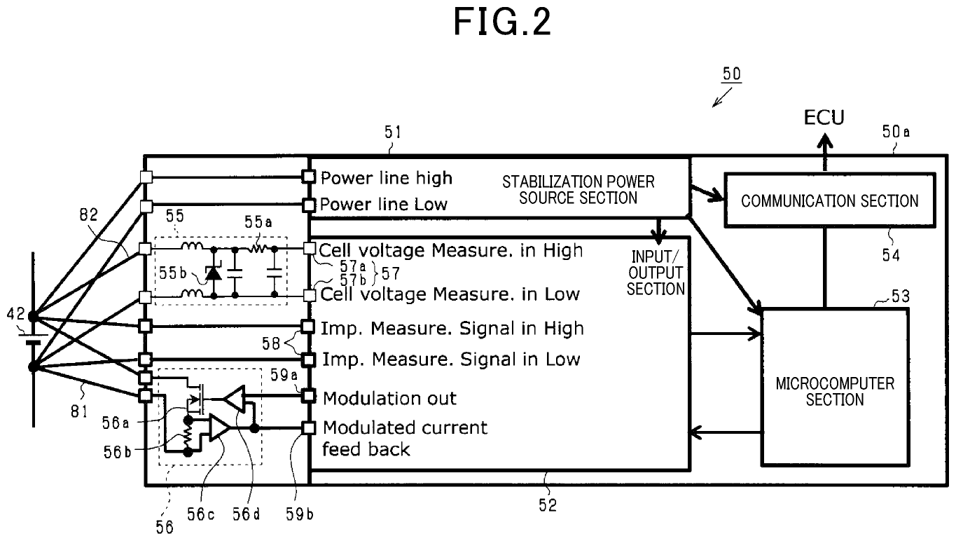

Next, a detailed description will be given on the battery measurement device 50. As illustrated in FIG. 2, the battery measurement device 50 is provided for each of the battery cells 42 in the first embodiment.

The battery measurement device 50 includes an ASIC section 50a, a filter section 55, and a current modulation circuit 56. The ASIC section 50a includes a stabilization power source supply section 51, an input/output section 52, a microcomputer section 53 serving as a calculation section, and a communication section 54.

The stabilization power source supply section 51 is connected to a power source line of the battery cell 42 and supplies an electric power supplied from the battery cell 42 to the input/output section 52, the microcomputer section 53, and the communication section 54. The input/output section 52, the microcomputer section 53, and the communication section 54 are driven based on the electric power.

The input/output section 52 is connected to the battery cell 42 that is a measurement target. Specifically speaking, the input/output section 52 includes a direct-current voltage input terminal 57 to which direct-current voltage can be input (measured) from the battery cell 42. The filter section 55 is provided between the battery cell 42 and the direct-current voltage input terminal 57. That is to say, an RC filter 55a serving as a filter circuit, a zener diode 55b serving as a protection element, and the like are provided between a positive-side terminal 57a and a negative-side terminal 57b of the direct-current voltage input terminal 57. In short, the RC filter 55a, the zener diode 55b, and the like are connected in parallel to the battery cell 42.

In addition, the input/output section 52 has a response signal input terminal 58 for inputting (measuring) a response signal (voltage variation) reflecting internal complex impedance information of the battery cell 42 between the terminals of the battery cell 42. This causes the input/output section 52 to function as a response signal measurement section.

In addition, the input/output section 52, which is connected to the current modulation circuit 56, includes an instruction signal output terminal 59a that outputs, to the current modulation circuit 56, an instruction signal indicating a sinusoidal signal (an alternating-current signal) to be outputted from the battery cell 42. The input/output section 52 also includes a feedback signal input terminal 59b. The feedback signal input terminal 59b receives a current signal, which is actually outputted (flows) from the battery cell 42, as a feedback signal (a measurement signal) via the current modulation circuit 56.

In addition, the input/output section 52, which is connected to the microcomputer section 53, is configured to output, to the microcomputer section 53, the direct-current voltage inputted to the direct-current voltage input terminal 57, the response signal inputted to the response signal input terminal 58, the feedback signal inputted to the feedback signal input terminal 59b, and the like. It should be noted that the input/output section 52, which includes an internal AD converter, is configured to convert an inputted analog signal to a digital signal and output the signal to the microcomputer section 53.

In addition, the input/output section 52 is configured to receive the instruction signal from the microcomputer section 53 and configured to output the instruction signal to the current modulation circuit 56 from the instruction signal output terminal 59a. It should be noted that the input/output section 52, which includes an internal DA converter, is configured to convert the digital signal inputted from the microcomputer section 53 to an analog signal and output the instruction signal to the current modulation circuit 56. In addition, the sinusoidal signal indicated to the current modulation circuit 56 by the instruction signal is subjected to a direct-current bias (an offset value) to prevent the sinusoidal signal from becoming a negative current (a countercurrent to the battery cell 42).

The current modulation circuit 56 is a circuit that causes a predetermined alternating-current signal to be outputted with use of the battery cell 42 that is the measurement target as a power source. Specifically speaking, the current modulation circuit 56 includes a semiconductor switch element 56a (for example, an MOSFET) serving as a signal control section and a resistance 56b serving as a shunt resistance connected in series to the semiconductor switch element 56a. A drain terminal of the semiconductor switch element 56a is connected to a positive-side power source terminal of the battery cell 42 and a source terminal of the semiconductor switch element 56a is connected in series to an end of the resistance 56b. In addition, the other end of the resistance 56b is connected to a negative-side power source terminal of the battery cell 42. The semiconductor switch element 56a is configured to be able to adjust the amount of a flowing current between the drain terminal and the source terminal. In addition, in order to adjust a voltage to be applied to the semiconductor switch element 56a in accordance with an operation region of the semiconductor switch element 56a, a resistance is inserted in series in the current modulation circuit in some cases.

In addition, the current modulation circuit 56 also includes a current measurement amplifier 56c (a current sense amplifier) serving as a current measurement section connected to both ends of the resistance 56b. The current measurement amplifier 56c is configured to measure signal (a current signal) flowing through the resistance 56b and output a measurement signal as a feedback signal to the feedback signal input terminal 59b of the input/output section 52.

The current modulation circuit 56 also includes a feedback circuit 56d. The feedback circuit 56d is configured to receive an input of the instruction signal from the instruction signal output terminal 59a of the input/output section 52 and an input of the feedback signal from the current measurement amplifier 56c. The feedback circuit 56d is then configured to compare the instruction signal and the feedback signal and output the result to a gate terminal of the semiconductor switch element 56a.

The semiconductor switch element 56a adjusts the amount of current between the drain and the source by adjusting a voltage to be applied to between the gate and the source to cause the sinusoidal signal (the predetermined alternating-current signal) indicated by the instruction signal to be outputted from the battery cell 42 based on the signal from the feedback circuit 56d. It should be noted that in a case where an error occurs between a waveform indicated by the instruction signal and a waveform actually flowing through the resistance 56b, the semiconductor switch element 56a adjusts the amount of current to cause the error to be corrected based on the signal from the feedback circuit 56d. This stabilizes the sinusoidal signal flowing through the resistance 56b.

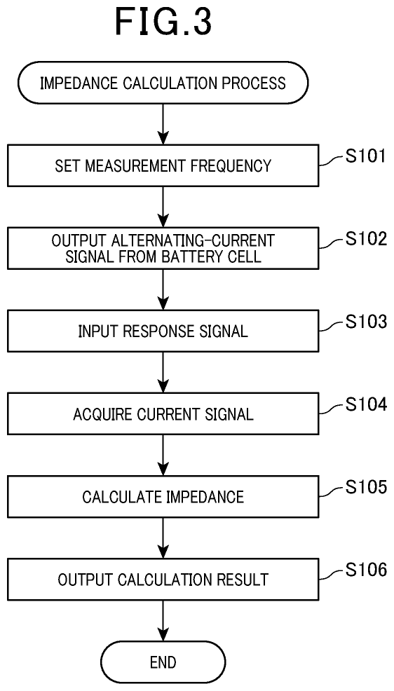

Next, description will be given on a method of calculating a complex impedance of the battery cell 42. The battery measurement device 50 performs an impedance calculation process illustrated in FIG. 3 in a predetermined cycle. In the impedance calculation process, the microcomputer section 53 sets a measurement frequency of the complex impedance (Step S101). The measurement frequency is set from among frequencies within a preset measurement range.

Next, the microcomputer section 53 decides a variety of parameters of an alternating-current signal (an alternating-current signal for measurement) to be outputted from the battery cell 42 and outputs, to the input/output section 52, an instruction signal indicating an instruction to output the alternating-current signal for measurement according to the variety of parameters (Step S102). In the present embodiment, the alternating-current signal for measurement is a sinusoidal signal. In this regard, the variety of parameters include, for example, an amplitude, frequency, offset value, phase, and the like of the alternating-current signal. Specifically, the microcomputer section 53 decides the frequency of the sinusoidal signal (the alternating-current signal for measurement) based on the measurement frequency. It should be noted that the amplitude and the offset value of the sinusoidal signal (the alternating-current signal for measurement) are preset values in the first embodiment.

In response to the input of the instruction signal, the input/output section 52 converts the signal to an analog signal through the DA converter and outputs the signal to the current modulation circuit 56. The current modulation circuit 56 causes the alternating-current signal for measurement to be outputted with use of the battery cell 42 as a power source based on the instruction signal. Specifically, the semiconductor switch element 56a adjusts the amount of current to cause the alternating-current signal for measurement indicated by the instruction signal to be outputted from the battery cell 42 based on the signal inputted via the feedback circuit 56d. The alternating-current signal for measurement is thus outputted from the battery cell 42.

When the alternating-current signal for measurement is caused to be outputted from the battery cell 42, that is, when a disturbance is applied to the battery cell 42, a voltage variation reflecting internal complex impedance information regarding the battery cell 42 occurs between the terminals of the battery cell 42. The input/output section 52 receives the voltage variation via the response signal input terminal 58 and outputs the voltage variation as a response signal to the microcomputer section 53. At this time, the signal is converted to a digital signal through the AD converter and outputted.

After the execution of Step S102, the microcomputer section 53 receives the response signal from the input/output section 52 (Step S103). In addition, the microcomputer section 53 acquires a current signal (i.e., the alternating-current signal for measurement outputted from the battery cell 42) flowing through the resistance 56b of the current modulation circuit 56 (Step S104). Specifically, the microcomputer section 53 receives, via the input/output section 52, an input of the feedback signal (the measurement signal) as the current signal outputted from the current measurement amplifier 56c.

Next, the microcomputer section 53 calculates information regarding the complex impedance of the battery cell 42 based on the response signal and the current signal (the feedback signal) (Step S105). In short, the microcomputer section 53 calculates all or one of an absolute value and a phase of the complex impedance based on a real part of the response signal, an imaginary part of the response signal, a real part of the current signal, an imaginary part of the current signal, and the like. The microcomputer section 53 outputs a calculation result to the ECU 60 via the communication section 54 (Step S106). The calculation process is then terminated.

The impedance calculation process is repeatedly performed until complex impedances of a plurality of frequencies within a measurement range are calculated. For example, the calculation process may be repeatedly performed until the measurement range is swept. The ECU 60 creates, for example, a complex impedance planar plot (a Cole-Cole plot) based on the calculation result and understands characteristics of the electrodes and the electrolyte. For example, the state of charge (SOC) and the state of deterioration (SOH) are understood.

It should be noted that the whole of the Cole-Cole plot is not necessarily created and attention may be focused on a part of the Cole-Cole plot. For example, a complex impedance of a specific frequency may be measured at regular time intervals during running and changes in SOC, SOH, battery temperature, and the like during running may be understood based on a temporal change in the complex impedance of the specific frequency. Alternatively, a complex impedance of a specific frequency may be measured at regular time intervals such as every day, every cycle, or every year and changes in SOH and the like may be understood based on a temporal change in the complex impedance of the specific frequency.

In the meanwhile, the feedback signal (the measurement signal) is unstable until the elapse of a certain time after the start of the output of the alternating-current signal in some cases. The cause is speculated to be, for example, a rise in resistance temperature of the resistance 56b or battery temperature due to a current flowing through the circuit and the occurrence of an influence of it (thermal drift). In short, it is speculated that a resistance value of the resistance 56b and an internal resistance of the battery cell 42 change with a rise in temperature, causing the occurrence of a change in measurement signal. Unstableness of the measurement signal leads to a degradation of a calculation accuracy of the complex impedance.

Accordingly, after the start of the output of the alternating-current signal from the battery cell 42 caused by the current modulation circuit 56, the microcomputer section 53 waits for the measurement result, or measurement signal (feedback signal), to reach a steady state and then calculates information regarding the complex impedance and outputs the calculation result. Specifically, it is performed as described below.

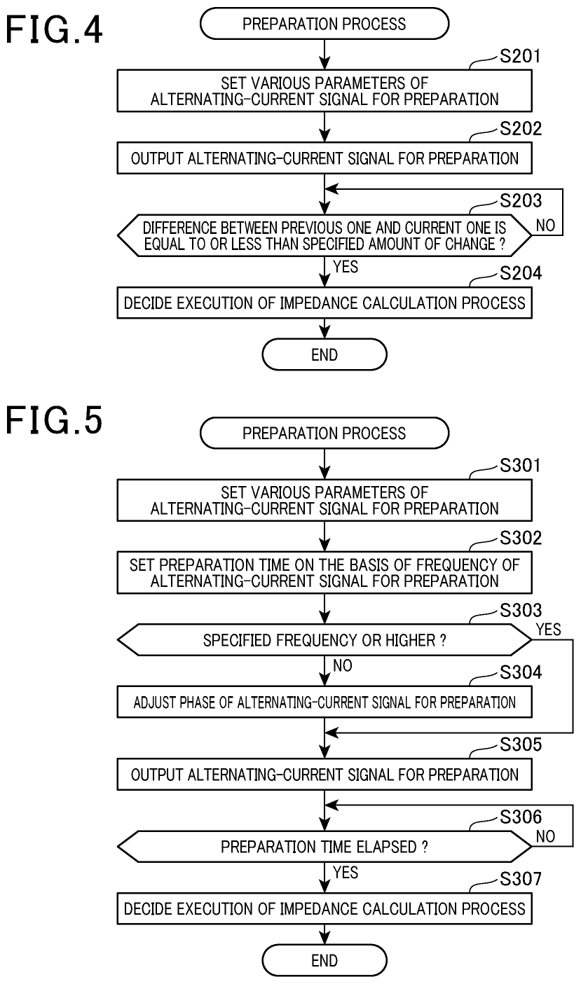

Before deciding the calculation of the complex impedance and performing the above-described impedance calculation process, the battery measurement device 50 performs a preparation process illustrated in FIG. 4. In the preparation process, the microcomputer section 53 of the battery measurement device 50 sets a variety of parameters regarding an alternating-current signal (an alternating-current signal for preparation) to be outputted from the battery cell 42 (Step S201). In the present embodiment, the alternating-current signal for preparation is assumed to be the same as an alternating-current signal for measurement (a sinusoidal signal). In short, the microcomputer section 53 may set the variety of parameters of the alternating-current signal for preparation as in Step S102. It should be noted that a frequency of the alternating-current signal for preparation is a measurement frequency of the complex impedance.

Next, the microcomputer section 53 outputs, to the input/output section 52, an instruction signal indicating an instruction to output the alternating-current signal for preparation according to the variety of parameters set in Step S201 (Step S202). In response to the input of the instruction signal, the input/output section 52 converts the signal to an analog signal through the DA converter and outputs the signal to the current modulation circuit 56. The current modulation circuit 56 causes the alternating-current signal for preparation to be outputted with use of the battery cell 42 as a power source based on the instruction signal.

Next, the microcomputer section 53 receives the measurement signal (the feedback signal), which is the current signal outputted from the current measurement amplifier 56c, via the input/output section 52 and determines whether a difference (a difference in amplitude) between the currently inputted measurement signal and the previously inputted measurement signal is equal to or less than a preset specified amount of change (Step S203). It should be noted that a negative determination is always made during the process in Step S203 performed for the first time since the start of the preparation process.

In response to the determination result being negative, the microcomputer section 53 again performs the process in Step S203 after the elapse of a predetermined unit of time. In short, the process is repeated until the difference of the measurement signal per unit of time becomes the specified amount of change or less. In other words, the preparation process is continued until the difference of the measurement signal per unit of time becomes the specified amount of change or less without performing the impedance calculation process.

In contrast, in response to the determination result in Step S203 being positive, the microcomputer section 53 determines that the steady state is reached and, accordingly, decides the execution of the impedance calculation process (Step S204). The preparation process is then terminated. After the termination of the preparation process, the microcomputer section 53 performs the impedance calculation process in every predetermined cycle as described above.

According to the above first embodiment, the following effects are obtainable.

After the start of the output of the alternating-current signal for preparation from the battery cell 42 caused by the current modulation circuit 56, the microcomputer section 53 waits for the measurement result, or measurement signal (the feedback signal), to reach a steady state and then calculates information regarding the complex impedance and outputs the calculation result. Thereafter, in the impedance calculation process, a rise in temperature due to the alternating-current signal for measurement is thus reduced to reduce an error of the measurement signal, which makes it possible to improve the calculation accuracy of the complex impedance.

In addition, the determination is made based on the measurement signal likely to be influenced by the resistance temperature of the resistance 56b or the battery temperature of the battery cell 42, which makes it possible to accurately determine whether the steady state is reached. In addition, it is also advantageous that the need for a special device, such as a temperature sensor, only for the determination of the steady state, is eliminated.

In the meanwhile, before shipping or during a regular inspection of the battery measurement device 50, an inspection device is connected to the battery measurement device 50 instead of the battery cell 42 to perform a performance inspection of the battery measurement device 50. At this time, since the microcomputer section 53 is configured to calculate information regarding the complex impedance after waiting for the feedback signal to reach the steady state as described above, it is possible to reduce an error in an inspection result.

A detailed description will be given below. First, description will be given on a flow of the performance inspection to be performed by the inspection device. In response to the microcomputer section 53 outputting an instruction signal for the current modulation circuit 56 to cause an alternating current to be outputted from the inspection device (a replacement for the battery cell 42), the inspection device outputs the alternating current corresponding to the instruction signal. At this time, the inspection device measures the outputted alternating current and calculates a voltage for inspection to be outputted as a result (a complex number) of multiplication of a preset impedance value (an impedance value for inspection) by the measured current value. The inspection device then outputs the calculated voltage for inspection to the battery measurement device 50. The battery measurement device 50 calculates a complex impedance based on the voltage for inspection and outputs the complex impedance. An operator or the inspection device inspects a performance of the battery measurement device 50 by comparing the complex impedance calculated by the battery measurement device 50 and the impedance value for inspection.

As described above, for the inspection device, calculation and output of the voltage for inspection require a process including the input of the instruction signal the output of the alternating current the measurement of the alternating current the calculation of the voltage for inspection the output of the voltage for inspection, and the like, which necessitates a predetermined latency. For this reason, in a case where the battery measurement device 50 starts the calculation of the complex impedance immediately after the output of the alternating-current signal for preparation, the voltage for inspection is not normally outputted immediately after the start, so that an error in the calculation result or an erroneous determination is highly likely to occur. Accordingly, the microcomputer section 53 is configured to calculate information regarding the complex impedance after waiting for the feedback signal to reach the steady state after the microcomputer section 53 causes the current modulation circuit 56 to start the output of the alternating-current signal for preparation as described above, which makes it possible to reduce a possibility of an erroneous determination during the above inspection made using the above-described inspection device. In short, in the battery measurement device 50, a predetermined latency before the output of the voltage for inspection is set, which makes it possible to reduce a possibility of an erroneous determination.

### Modification Examples of First Embodiment

Description will be given below on modification examples where the configuration of the first embodiment is partly modified.
In the above first embodiment, in a case where the determination based on the measurement signal (Step S203) is positive, the steady state is determined to be reached. However, the steady state may be determined to be reached at the elapse of a predetermined preparation time after the start of the output of the alternating-current signal for preparation. The predetermined time may be set based on an experiment, a simulation, or the like. It should be noted that the preparation time may be changed in accordance with a temperature outside the vehicle, the resistance temperature of the resistance 56b, and the battery temperature. For example, in a case where the temperature outside the vehicle, the resistance temperature of the resistance 56b, and the battery temperature are high, the preparation time may be shortened. Alternatively, the preparation time may be changed based on the elapsed time after the latest calculation of the complex impedance. For example, in a case where the elapsed time after the latest calculation of the complex impedance is short, the preparation time may be shortened.
In the preparation process of the above first embodiment, after causing an alternating-current signal for preparation to be outputted, the microcomputer section 53 may calculate the complex impedance based on a response signal (a voltage variation) responsive to the alternating-current signal for preparation and a measurement signal (a current signal) and determine whether a difference (a difference from the previous value) in magnitude (absolute value) of the complex impedance becomes the predetermined specified amount of change or less. In short, it may be determined whether a difference of the complex impedance per unit of time becomes the predetermined specified amount of change or less. Then, in a case where a result of the determination based on the complex impedance is positive, the microcomputer section 53 may determine that the steady state is reached and, accordingly, decide the execution of the impedance calculation process.
In the above first embodiment, a resistance temperature detection section that detects the resistance temperature of the resistance 56b may be provided and, after the output of an alternating-current signal for preparation, the microcomputer section 53 may determine whether the measured resistance temperature reaches a predetermined resistance temperature or whether the amount of change in resistance temperature (the amount of change from the previous value) becomes a predetermined amount of change in resistance temperature or less. Then, in a case where the determination based on the resistance temperature is positive, the microcomputer section 53 may determine that the steady state has been reached and, accordingly, decide the execution of the impedance calculation process.
In the above first embodiment, a battery temperature sensor serving as a battery temperature detection section that detects the battery temperature of the battery cell 42 may be provided and, after the output of an alternating-current signal for preparation, the microcomputer section 53 may determine whether the measured battery temperature reaches a predetermined battery temperature or whether the amount of change in battery temperature (the amount of change from the previous value) becomes a predetermined amount of change in battery temperature or less. Then, in a case where the determination based on the battery temperature is positive, the microcomputer section 53 may determine that the steady state is reached and, accordingly, decide the execution of the impedance calculation process.
The above first embodiment may be implemented in combination with any one of the above modification examples of the first embodiment. For example, two or more selected from among the determination based on a measurement signal (Step S203), the determination based on a complex impedance, the determination based on a resistance temperature, and the determination based on a battery temperature may be performed and, in a case where measurement results are all positive, the microcomputer section 53 may determine that the steady state is reached.

### Second Embodiment

The configuration of the above first embodiment may be modified as in a second embodiment below. In the second embodiment, description will be given below mainly on a different part from the configuration described in the above embodiments. In addition, in the second embodiment, a basic configuration will be described by taking the power source system 10 of the first embodiment as an example.

Description will be given on a preparation process of the second embodiment based on FIG. 5. In the preparation process of the second embodiment, the battery measurement device 50 sets a variety of parameters of an alternating-current signal for preparation to be outputted from the battery cell 42 during the preparation process (Step S301). In the second embodiment, the alternating-current signal for preparation is assumed to be the same as the alternating-current signal for measurement (the sinusoidal signal) in Step S101. In short, a frequency of the alternating-current signal for preparation of the second embodiment is a measurement frequency.

Next, the microcomputer section 53 sets, in accordance with the frequency of the alternating-current signal for preparation, time predicted to be required before the steady state is reached after the start of the output of the alternating-current signal for preparation (hereinafter, referred to as preparation time) (Step S302). The preparation time according to the frequency of the alternating-current signal for preparation is set based on an experiment, a simulation, or the like and stored in advance. It should be noted that whether the steady state is reached during the experiment or the like may be comprehensively determined in accordance with the measurement signal, the calculation result of a complex impedance, the resistance temperature, the battery temperature, or a combination of them as in the first embodiment or the modification examples of the first embodiment.

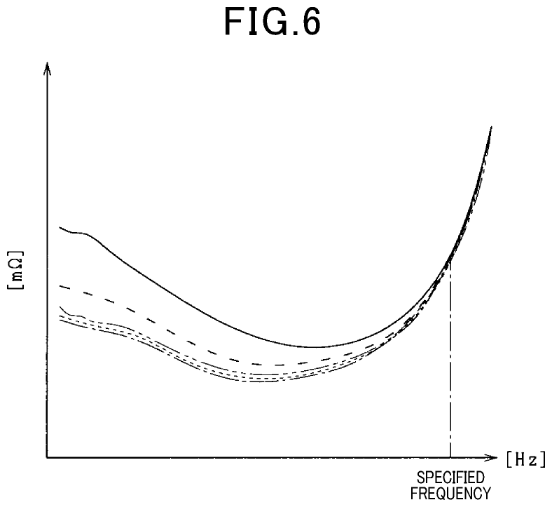

In the meanwhile, it has been found that in a case where the measurement frequency is less than a specified frequency, the measurement signal varies depending on a phase of the alternating-current signal for preparation at the time of the start of output. In short, it has been found that the temperature fails to be sufficiently raised, causing the required preparation time to vary. A detailed description will be given based on FIG. 6. FIG. 6 illustrates a relationship between a real part of the complex impedance and the measurement frequency. In FIG. 6, the complex impedance is calculated after the elapse of the preparation time after the start of the output of the alternating-current signal for preparation and the calculation result is illustrated. In FIG. 6, a line style is changed in accordance with a difference in phase at the start of the output of the alternating-current signal for preparation. As illustrated in FIG. 6, in a case where the measurement frequency is equal to or more than a certain frequency (a specified frequency), almost no difference in calculation result occurs irrespective of a difference in phase at the start of the output of the alternating-current signal for preparation.

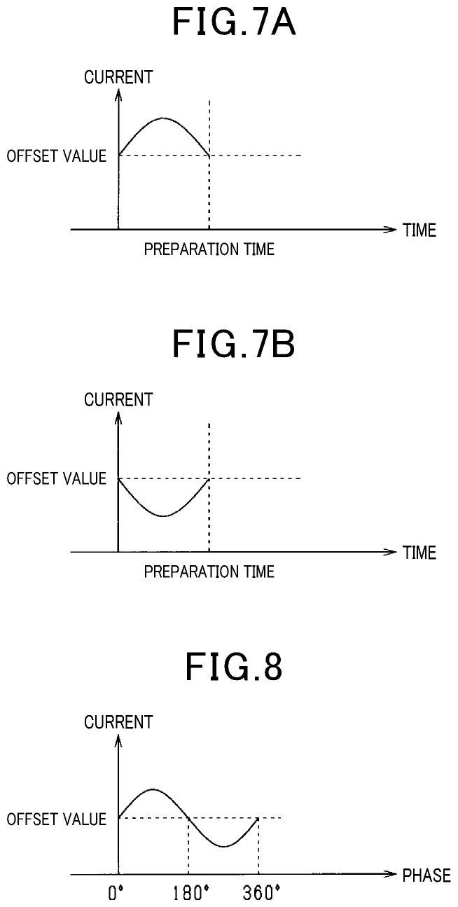

In contrast, in case where the measurement frequency is less than the certain frequency (the specified frequency), the calculation result varies depending on a difference in phase at the start of the output of the alternating-current signal for preparation. This is considered to be because in a case where the frequency is low, before the elapse of the preparation time, a ratio of a time range where a current value based on the alternating-current signal for preparation is larger than an offset value (a current bias) may become large (see FIG. 7(a)) or may become small (see FIG. 7(b)) depending on the phase at the start of output. It should be noted that FIG. 7 illustrates an extreme case for the convenience of illustration. In contrast, in a case where the measurement frequency is equal to or more than the specified frequency, the current value is averaged by the elapse of the preparation time to reduce an influence of the current value, so that no variation is assumed to occur.

Accordingly, in the second embodiment, the microcomputer section 53 determines whether the frequency of the alternating-current signal for preparation is equal to or more than specified frequency (Step S303). In a case where the determination result in Step S303 is negative (in a case where the frequency is less than the specified frequency), the microcomputer section 53 sets (adjusts) the phase of the alternating-current signal (Step S304). Specifically, the microcomputer section 53 sets the phase of the alternating-current signal for preparation at the start of output to cause the current value of the alternating-current signal for preparation at the start of output to become larger than the offset value and cause an inclination of the current based on the alternating-current signal for preparation at the start of output to become positive. In short, in a case where the alternating-current signal for preparation is a sinusoidal signal as illustrated in FIG. 8, the phase at the start of output is caused to be zero (0°).

After the process in Step S304 or in a case where the determination result in Step S303 is positive (in a case where the frequency is equal to or more than the specified frequency), the microcomputer section 53 outputs, to the input/output section 52, an instruction signal indicating an instruction to output the alternating-current signal for preparation according to the variety of parameters set in Step S301 or Step S304 (Step S305). In response to the input of the instruction signal, the input/output section 52 converts the signal to an analog signal through the DA converter and outputs the signal to the current modulation circuit 56. The current modulation circuit 56 causes the alternating-current signal for preparation to be outputted with use of the battery cell 42 as a power source based on the instruction signal.

Then, the microcomputer section 53 waits until the elapse of the preparation time set in Step S302 (Step S306). The microcomputer section 53 determines that the steady state is reached after the elapse of the preparation time set in Step S302 and, accordingly, decides the execution of the impedance calculation process (Step S307). The preparation process is then terminated. After the termination of the preparation process, the microcomputer section 53 performs the impedance calculation process in every predetermined cycle as described above.

According to the above second embodiment, the following effects are obtainable.

The calculation of the complex impedance is started after the elapse of the preparation time after the start of the output of the alternating-current signal for preparation. This reduces a rise in temperature due to the alternating-current signal for measurement to reduce an error of the measurement signal, which makes it possible to improve the calculation accuracy of the complex impedance.

The preparation time is changed in accordance with the frequency of the alternating-current signal for preparation. This makes it possible to set an appropriate preparation time. In addition, in a case where the frequency of the alternating-current signal for preparation (in the above embodiment, the measurement frequency) is less than the specified frequency, there is a possibility that the required preparation time differs under the influence of the phase at the start of output. Accordingly, in a case where the measurement frequency is less than the specified frequency, the phase at the start of output is adjusted. Specifically, the microcomputer section 53 sets the phase of the alternating-current signal for preparation at the start of output to cause the current value of the alternating-current signal for preparation at the start of output to become larger than the offset value and cause an inclination of the current based on the alternating-current signal for preparation at the start of output to become positive. For example, in a case where the alternating-current signal for preparation is a sinusoidal signal, the phase at the start of output is caused to be zero. This makes it possible to reduce the occurrence of an error in the calculation result to shorten a standby time.

### Modification Examples of Second Embodiment

Description will be given below on modification examples where the configuration of the second embodiment is partly modified.
In the above second embodiment, the alternating-current signal for preparation may not be adjusted. In this case, in consideration of an influence of the phase of the alternating-current signal for preparation at the start of output, the preparation time may be set with the assumption that the preparation time becomes the longest. Specifically, the microcomputer section 53 may set the preparation time with the assumption that the current value of the alternating-current signal at the start of output becomes equal to or less than the offset value and the inclination of the current based on the alternating-current signal at the start of output is negative. For example, the microcomputer section 53 may set the preparation time with the assumption that the phase of the alternating-current signal for preparation at the start of output is 180°. This simplifies the process.
In the above second embodiment, in a case where the phase of the alternating-current signal for preparation is not adjusted and the frequency of the alternating-current signal for preparation is less than the specified frequency, the preparation time may be changed in accordance with the phase and the frequency of the alternating-current signal at the start of input/output. For example, the preparation time may be changed in accordance with, during the preparation time, whether the ratio of the time range where the current value based on the alternating-current signal for preparation is larger than the offset value becomes large (see FIG. 7(a)) or becomes small (see FIG. 7(b)) depending on a difference between different phases even though the frequency is the same.
In the above second embodiment, the microcomputer section 53 sets the phase at the start of output at zero (0°) but may set the phase within a range equal to or more than 0° and less than 90°.

### Third Embodiment

The configuration of the above first embodiment may be modified as in a third embodiment below. In the third embodiment, description will be given below mainly on a different part from the configuration described in the above embodiments. In addition, in the third embodiment, a basic configuration will be described by taking the power source system 10 of the first embodiment as an example.

First, description will be given on a method of deciding a variety of parameters of an alternating-current signal for measurement in Step S101 of an impedance calculation process of the third embodiment. In Step S101 of the impedance calculation process, the microcomputer section 53 estimates a magnitude of a complex impedance. For example, with a previously measured value (for example, a cole-cole plot or the like) of the complex impedance be stored, the microcomputer section 53 may estimate the magnitude of the complex impedance based on the measurement frequency. Alternatively, with a map of the complex impedance being created by experiment or the like, the magnitude of the complex impedance calculated with reference to the map may be estimated based on parameters related to a battery state such as previously measured degree of deterioration (SOH), measurement frequency, battery temperature, and the like. In this case, the microcomputer section 53 functions as an estimation section.

The microcomputer section 53 then sets an amplitude of the alternating-current signal for measurement in accordance with the estimated magnitude of the complex impedance. Specifically speaking, in a case where the magnitude of the complex impedance is small, an increase in amplitude makes it possible to perform calculation accurately. Accordingly, in a case where the magnitude of the complex impedance is estimated to be smaller than a predetermined value, the microcomputer section 53 sets a large amplitude from among settable amplitudes. In contrast, in a case where the magnitude of the complex impedance is large, accurate calculation is possible even when the amplitude is reduced. Accordingly, in a case where the magnitude of the complex impedance is estimated to be equal to or more than the predetermined value, the microcomputer section 53 sets a small amplitude from among the settable amplitudes. It should be noted that the amplitude may be set from among the settable amplitudes to cause the amplitude to be inversely proportional to the magnitude of the complex impedance.

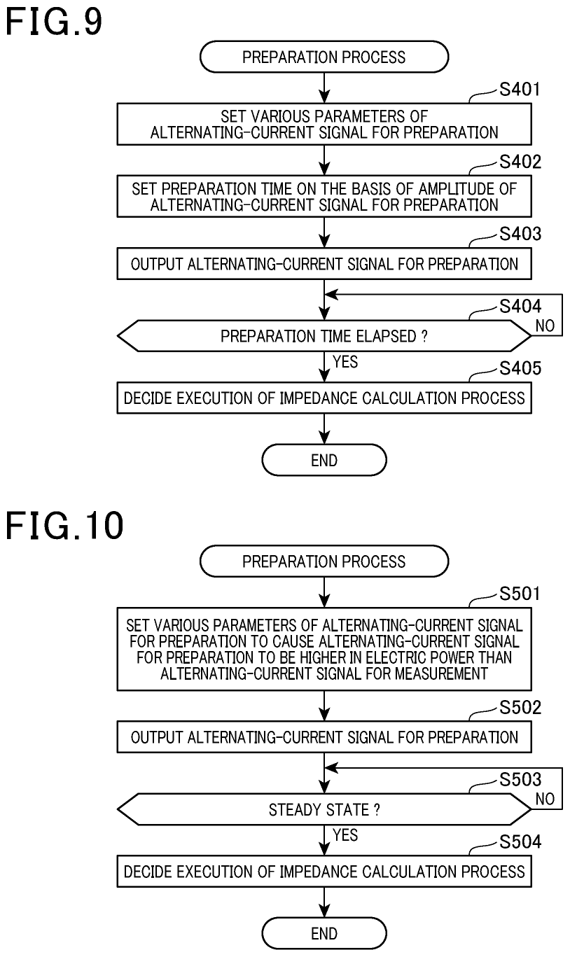

Next, description will be given on a preparation process of the third embodiment with reference to FIG. 9. In the preparation process, the battery measurement device 50 sets a variety of parameters regarding an alternating-current signal (an alternating-current signal for preparation) to be outputted from the battery cell 42 (Step S401). In the present embodiment, the alternating-current signal for preparation is assumed to be the same as the alternating-current signal for measurement (a sinusoidal signal) in Step S101. It should be noted that the frequency of the alternating-current signal for preparation is a frequency for measurement set during the impedance calculation process performed first.

Next, the microcomputer section 53 sets a preparation time required before the steady state is reached after the start of the output of a signal based on an amplitude of the alternating-current signal for preparation (Step S402). In the third embodiment, the amplitude of the alternating-current signal for preparation is changed in accordance with the amplitude of the alternating-current signal for measurement. Then, it has been found that an effective electric power increases with an increase in amplitude of the alternating-current signal for preparation and thus the resistance 56b and the battery temperature are likely to rise. Accordingly, it is sufficient if time proportional to the amplitude of the alternating-current signal for preparation is set as the time required before the steady state is reached after the start of the output of the alternating-current signal for preparation. It should be noted that in response to the amplitude being equal to or more than the predetermined value, a first time may be set as the preparation time, whereas in response to the amplitude being less than the predetermined value, a second time shorter than the first time may be set. In addition, an appropriate preparation time according to the amplitude of the alternating-current signal for preparation may be identified by experiment or the like.

Next, the microcomputer section 53 outputs, to the input/output section 52, an instruction signal indicating an instruction to output the alternating-current signal for preparation according to the variety of parameters set in Step S401 (Step S403). In response to the input of the instruction signal, the input/output section 52 converts the signal to an analog signal through the DA converter and outputs the signal to the current modulation circuit 56. The current modulation circuit 56 causes the alternating-current signal for preparation to be outputted with use of the battery cell 42 as a power source based on the instruction signal.

Next, the microcomputer section 53 determines whether the preparation time set in Step S402 has elapsed (Step S404). In a case where the determination result is negative, the microcomputer section 53 again performs the process in Step S404 after the elapse of a predetermined time. In short, the microcomputer section 53 stands by until the elapse of the preparation time. In contrast, in response to the determination result in Step S404 being positive, the microcomputer section 53 determines that the steady state is reached and, accordingly, decides the execution of the impedance calculation process (Step S405). The preparation process is then terminated. After the termination of the preparation process, the microcomputer section 53 performs the impedance calculation process in every predetermined cycle as described above.

According to the above third embodiment, the following effects are obtainable. The calculation of the complex impedance is started after the elapse of the preparation time after the start of the output of the alternating-current signal for preparation. This reduces a rise in temperature due to the alternating-current signal for measurement to reduce an error of the measurement signal, which makes it possible to improve the calculation accuracy of the complex impedance. At this time, the preparation time is changed in accordance with the amplitude of the alternating-current signal for preparation. This makes it possible to set an appropriate preparation time.

The microcomputer section 53 sets an appropriate amplitude of the alternating-current signal for measurement in accordance with the estimated magnitude of the complex impedance. This makes it possible to improve the calculation accuracy of the complex impedance.

### Fourth Embodiment

The configuration of the above first embodiment may be modified as in a fourth embodiment below. In the fourth embodiment, description will be given below mainly on a different part from the configuration described in the above embodiments. In addition, in the fourth embodiment, a basic configuration will be described by taking the power source system 10 of the first embodiment as an example.

Description will be given on a preparation process of the fourth embodiment with reference to FIG. 10. In the preparation process, the battery measurement device 50 sets a variety of parameters of an alternating-current signal for preparation to be outputted from the battery cell 42 (Step S501). In the present embodiment, the alternating-current signal for preparation is assumed to be a signal with a larger electric power (effective electric power) than the alternating-current signal for measurement in Step S101. For example, the microcomputer section 53 sets the alternating-current signal for preparation by causing the amplitude to be larger than the amplitude of the alternating-current signal for measurement. The processes in Step S502 and the subsequent steps are similar to those in Step S202 and the subsequent steps in the first embodiment and, accordingly, detailed descriptions thereof are omitted.

According to the above fourth embodiment, the following effects are obtainable.

The alternating-current signal for preparation with a larger effective electric power than the alternating-current signal for measurement is outputted and the calculation of the complex impedance is started after the measurement result reaches the steady state. As compared with a case where the same parameters as those of the alternating-current signal for measurement are set as the variety of parameters of the alternating-current signal for preparation, it is possible to shorten time required before the steady state is reached.

### Modification Examples of Fourth Embodiment

In Step S503 of the above fourth embodiment, whether the steady state is reached may be determined by a method similar to the method of the first embodiment and the modification examples of the first embodiment. That is to say, it is sufficient if one or more selected from among the determination based on the measurement signal (Step S203), the determination based on the complex impedance, the determination based on the resistance temperature, and the determination based on the battery temperature are performed and, in response to the determination results being positive, the microcomputer section 53 determines that the steady state is reached.
In the above fourth embodiment, a resistance temperature sensor that measures the resistance temperature of the resistance 56b or a battery temperature sensor that measures the battery temperature of the battery cell 42 may be provided, allowing the variety of parameters of the alternating-current signal for preparation to be set to cause the magnitude of the electric power to be changed in accordance with the resistance temperature or the battery temperature. For example, the microcomputer section 53 may set the variety of parameters of the alternating-current signal for preparation to cause the electric power to become large in a case where the resistance temperature or the battery temperature at the start of the output of the alternating-current signal for preparation is equal to or less than a threshold as compared with in a case where the resistance temperature or the battery temperature is higher than the threshold.
In the above fourth embodiment, the microcomputer section 53 may change the variety of parameters of the alternating-current signal for preparation to cause the electric power to gradually decrease until the steady state is reached after the start. In this manner, it is possible to prevent the temperature (the resistance temperature or the battery temperature) from extremely rising. In addition, it is possible to reduce an influence (induced electromotive force or the like) based on a rapid change in the current value.

### Other Modification Examples

In the preparation process of the above second embodiment or the above third embodiment, the variety of parameters of the alternating-current signal for preparation may be set to cause the electric power to be larger than that of the alternating-current signal for measurement as in the fourth embodiment. This makes it possible to shorten the preparation time.
In the above embodiments and modification examples, the battery measurement device 50 may measure impedances of battery cells 42 connected in parallel. In short, to increase a battery capacity, a plurality of battery cells 42 may be connected in parallel to form a single unit (a battery module) as a whole. Likewise, the battery measurement device 50 may measure impedances of the battery cells 42 connected in series. In short, a plurality of battery cells 42 may be connected in series to form a single unit (a battery module) as a whole.
In the above embodiments, the battery measurement device 50 may cause an alternating-current signal to be inputted from an external power source to the battery cell 42 (or a battery module 41), measure a response signal (a voltage variation) responsive to the alternating-current signal and a current signal, and calculate the complex impedance based on the signals.
In the above embodiments, the preparation time may be changed in accordance with type of vehicle.
The battery measurement device 50 of the above embodiments may be used in, as a vehicle, an HEV, an EV, a PHV, an auxiliary battery, an electric airplane, an electric motorcycle, or an electric ship. In addition, in the above embodiments, the battery cells 42 may be connected in parallel.
Although the alternating-current signal of the above embodiments is assumed to be a sinusoidal signal, it may be changed as desired as long as being an alternating-current signal and may be a rectangular wave, a triangular wave, or the like.

The disclosure herein is not limited to the exemplified embodiments. The disclosure encompasses the exemplified embodiments and modifications by those skilled in the art based thereon. For example, the disclosure is not limited to combinations of components and/or elements described in the embodiments. The disclosure may be implemented in various combinations. The disclosure may have additional portions that may be added to the embodiments. The disclosure encompasses omission of components and/or elements of the embodiments. The disclosure encompasses replacement or combination of components and/or elements between one embodiment and another. The disclosed technical scope is not limited to the descriptions of the embodiments. Several technical scopes disclosed are indicated by the descriptions in the claims and should further be understood to include all modifications within meaning and scope equivalent to the descriptions in the claims.

The control section and the method therefor described in the present disclosure may be implemented by a dedicated computer including a processor programmed to execute one or a plurality of functions embodied by computer programs and a memory. Alternatively, the control section and the method therefor described in the present disclosure may be implemented by a dedicated computer including a processor including one or more dedicated hardware logic circuits. In place of the above, the control section and the method described in the present disclosure may be implemented by one or more dedicated computers including a combination of a processor programmed to execute one or a plurality of functions and a memory and a processor including one or more hardware logic circuits. Moreover, the computer programs may be stored, as instructions to be executed by a computer, in a tangible non-transitory computer-readable recording medium.

Although the present disclosure has been described in reference to the embodiments, it should be understood that the present disclosure is not limited to the embodiments and structures. The present disclosure also encompasses various modification examples and modifications within the equivalent range. In addition, various combinations and forms, as well as other combinations and forms including only one element, more or less, are within the scope and spirit of the present disclosure.

What is claimed is:

1. A battery measurement device that measures a state of a secondary battery, the battery measurement device comprising:
a signal control section that causes an alternating-current signal to be outputted from the secondary battery or inputs an alternating-current signal to the secondary battery;
a current measurement section that measures the alternating-current signal;
a response signal measurement section that measures a response signal of the secondary battery responsive to the alternating-current signal; and
an arithmetic section that calculates information regarding a complex impedance of the secondary battery on a basis of measurement results of the alternating-current signal measured by the current measurement section and the response signal measured by the response signal measurement section, wherein
the arithmetic section calculates the information regarding the complex impedance after waiting for the measurement result of the alternating-current signal to reach a steady state after start of the input/output of the alternating-current signal by the signal control section and outputs a calculation result,
the arithmetic section is configured to determine that the measurement result reaches the steady state at elapse of a predetermined preparation time after the start of the input/output of the alternating-current signal to the secondary battery by the signal control section and output the calculation result, and
the preparation time is set in accordance with a frequency of the alternating-current signal to be inputted/outputted during a period before the measurement result reaches the steady state after the start of the input/output of the alternating-current signal by the signal control section.

2. The battery measurement device according to claim 1, wherein
the alternating-current signal is subjected to a direct-current bias, and
in response to the frequency of the alternating-current signal to be inputted/outputted during the period before the measurement result reaching the steady state after the start of the input/output of the alternating-current signal by the signal control section is less than a specified frequency, a phase of the alternating-current signal at the start of the input/output is set to cause a current value based on the alternating-current signal at the start of the input/output to become equal to or more than the direct-current bias and an inclination of the current value based on the alternating-current signal at the start of the input/output to become positive.

3. A battery measurement device that measures a state of a secondary battery, the battery measurement device comprising:
a signal control section that causes an alternating-current signal to be outputted from the secondary battery or inputs an alternating-current signal to the secondary battery;
a current measurement section that measures the alternating-current signal;
a response signal measurement section that measures a response signal of the secondary battery responsive to the alternating-current signal; and
an arithmetic section that calculates information regarding a complex impedance of the secondary battery on a basis of measurement results of the alternating-current signal measured by the current measurement section and the response signal measured by the response signal measurement section, wherein
the arithmetic section calculates the information regarding the complex impedance after waiting for the measurement result of the alternating-current signal to reach a steady state after start of the input/output of the alternating-current signal by the signal control section and outputs a calculation result,
the arithmetic section is configured to determine that the measurement result reaches the steady state at elapse of a predetermined preparation time after the start of the input/output of the alternating-current signal to the secondary battery by the signal control section and output the calculation result, and
the preparation time is set in accordance with an amplitude of the alternating-current signal to be inputted/outputted during a period before the measurement result reaches the steady state after the start of the input/output of the alternating-current signal by the signal control section.

4. The battery measurement device according to claim 3, comprising:
an estimation section that estimates the complex impedance of the secondary battery, wherein the amplitude of the alternating-current signal to be inputted/outputted is set in accordance with an absolute value of the complex impedance estimated by the estimation section.

5. A battery measurement device that measures a state of a secondary battery, the battery measurement device comprising:
a signal control section that causes an alternating-current signal to be outputted from the secondary battery or inputs an alternating-current signal to the secondary battery;
a current measurement section that measures the alternating-current signal;
a response signal measurement section that measures a response signal of the secondary battery responsive to the alternating-current signal; and
an arithmetic section that calculates information regarding a complex impedance of the secondary battery on a basis of measurement results of the alternating-current signal measured by the current measurement section and the response signal measured by the response signal measurement section, wherein
the arithmetic section calculates the information regarding the complex impedance after waiting for the measurement result of the alternating-current signal to reach a steady state after start of the input/output of the alternating-current signal by the signal control section and outputs a calculation result, and
the arithmetic section calculates the information regarding the complex impedance of the secondary battery after the start of the input/output of the alternating-current signal to the secondary battery by the signal control section, and determines that the measurement result reaches the steady state when an amount of change in magnitude of the complex impedance per unit of time becomes a specified amount of change or less and outputs the calculation result since then.

6. The battery measurement device according to claim 1, wherein
the arithmetic section calculates the information regarding the complex impedance of the secondary battery after the start of the input/output of the alternating-current signal to the secondary battery by the signal control section, and determines that the measurement result reaches the steady state when an amount of change in magnitude of the complex impedance per unit of time becomes a specified amount of change or less and outputs the calculation result since then.

7. A battery measurement device that measures a state of a secondary battery, the battery measurement device comprising:
a signal control section that causes an alternating-current signal to be outputted from the secondary battery or inputs an alternating-current signal to the secondary battery;
a current measurement section that measures the alternating-current signal;
a response signal measurement section that measures a response signal of the secondary battery responsive to the alternating-current signal; and
an arithmetic section that calculates information regarding a complex impedance of the secondary battery on a basis of measurement results of the alternating-current signal measured by the current measurement section and the response signal measured by the response signal measurement section, wherein
the arithmetic section calculates the information regarding the complex impedance after waiting for the measurement result of the alternating-current signal to reach a steady state after start of the input/output of the alternating-current signal by the signal control section and outputs a calculation result,
the current measurement section is configured to measure the alternating-current signal via a shunt resistance,
a resistance temperature detection section that detects a resistance temperature of the shunt resistance is provided, and
the arithmetic section determines that the measurement result reaches the steady state when the resistance temperature reaches a predetermined resistance temperature after the start of the input/output of the alternating-current signal to the secondary battery by the signal control section or when an amount of change in the resistance temperature per unit of time becomes a predetermined amount of change in the resistance temperature or less, calculates the information regarding the complex impedance, and outputs the calculation result.

8. The battery measurement device according to claim 1, wherein
the current measurement section is configured to measure the alternating-current signal via a shunt resistance,
a resistance temperature detection section that detects a resistance temperature of the shunt resistance is provided, and
the arithmetic section determines that the measurement result reaches the steady state when the resistance temperature reaches a predetermined resistance temperature after the start of the input/output of the alternating-current signal to the secondary battery by the signal control section or when an amount of change in the resistance temperature per unit of time becomes a predetermined amount of change in the resistance temperature or less, calculates the information regarding the complex impedance, and outputs the calculation result.

9. A battery measurement device that measures a state of a secondary battery, the battery measurement device comprising:
a signal control section that causes an alternating-current signal to be outputted from the secondary battery or inputs an alternating-current signal to the secondary battery;
a current measurement section that measures the alternating-current signal;
a response signal measurement section that measures a response signal of the secondary battery responsive to the alternating-current signal;
an arithmetic section that calculates information regarding a complex impedance of the secondary battery on a basis of measurement results of the alternating-current signal measured by the current measurement section and the response signal measured by the response signal measurement section; and
a battery temperature detection section, wherein
the arithmetic section calculates the information regarding the complex impedance after waiting for the measurement result of the alternating-current signal to reach a steady state after start of the input/output of the alternating-current signal by the signal control section and outputs a calculation result,
the battery temperature detection section detects a battery temperature of the secondary battery, and
the arithmetic section determines that the measurement result reaches the steady state when the battery temperature reaches a predetermined battery temperature after the start of the input/output of the alternating-current signal to the secondary battery by the signal control section or when an amount of change in the battery temperature per unit of time becomes a predetermined amount of change in the battery temperature or less, calculates the information regarding the complex impedance, and outputs the calculation result.

10. The battery measurement device according to claim 1, comprising:
a battery temperature detection section that detects a battery temperature of the secondary battery, wherein
the arithmetic section determines that the measurement result reaches the steady state when the battery temperature reaches a predetermined battery temperature after the start of the input/output of the alternating-current signal to the secondary battery by the signal control section or when an amount of change in the battery temperature per unit of time becomes a predetermined amount of change in the battery temperature or less, calculates the information regarding the complex impedance, and outputs the calculation result.

11. A battery measurement device that measures a state of a secondary battery, the battery measurement device comprising:
a signal control section that causes an alternating-current signal to be outputted from the secondary battery or inputs an alternating-current signal to the secondary battery;
a current measurement section that measures the alternating-current signal;
a response signal measurement section that measures a response signal of the secondary battery responsive to the alternating-current signal; and
an arithmetic section that calculates information regarding a complex impedance of the secondary battery on a basis of measurement results of the alternating-current signal measured by the current measurement section and the response signal measured by the response signal measurement section, wherein
the arithmetic section calculates the information regarding the complex impedance after waiting for the measurement result of the alternating-current signal to reach a steady state after start of the input/output of the alternating-current signal by the signal control section and outputs a calculation result, and
the signal control section causes an alternating-current signal for measurement to be inputted/outputted after the measurement result reaches the steady state, and causes an alternating-current signal for preparation with a larger effective electric power than the alternating-current signal for measurement to be inputted/outputted during a period before the measurement result reaches the steady state after the start of the input/output of the alternating-current signal by signal control section.

12. The battery measurement device according to claim 1, wherein
the signal control section causes an alternating-current signal for measurement to be inputted/outputted after the measurement result reaches the steady state, and causes an alternating-current signal for preparation with a larger effective electric power than the alternating-current signal for measurement to be inputted/outputted during the period before the measurement result reaches the steady state after the start of the input/output of the alternating-current signal by signal control section.

13. The battery measurement device according to claim 11, wherein
if a resistance temperature of a shunt resistance or a battery temperature is low, the signal control section sets a variety of parameters of the alternating-current signal for preparation on a basis of the resistance temperature of the shunt resistance or the battery temperature to increase the effective electric power.

14. The battery measurement device according to claim 12, wherein
if a resistance temperature of a shunt resistance or a battery temperature is low, the signal control section sets a variety of parameters of the alternating-current signal for preparation on a basis of the resistance temperature of the shunt resistance or the battery temperature to increase the effective electric power.
